(19) United States
(12) Patent Application Publication
(10) Pub. No.: US 2026/0143624 A1
(43) Pub. Date: May 21, 2026

(54) CASE WITH MULTI-LAYER PARTITIONED CHAMBERS

(71) Applicant: Dongguan Jianxin Electronic Technology Co., Ltd., Dongguan (CN)

(72) Inventor: HaoQiang DENG, Dongguan (CN)

(21) Appl. No.: 19/003,962

(22) Filed: Dec. 27, 2024

(30) Foreign Application Priority Data
Nov. 15, 2024 (CN) 2024227937163

(51) Int. Cl. H05K 7/20

(52) U.S. Cl. CPC H05K 7/20009

(57) ABSTRACT

A case with multi-layer partitioned chambers is provided. The case includes a framework, a first chamber and a second chamber arranged on the framework. The first chamber is used to place a graphics card, and the second chamber is used to place a power supply. The first chamber is located above the second chamber and is spaced apart from the second chamber, and the first chamber is provided with a plurality of first ventilation holes on one end face near the second chamber. The objective of this present disclosure is to provide a case with multi-layer partitioned chambers, which solves the problem of graphics card heat dissipation affected by the internal power supply and other components of the traditional case through a layered multi chamber design.

### CROSS-REFERENCE TO RELATED APPLICATIONS

This application claims to the benefit of priority from Chinese Application No. 202422793716.3 with a filing date of Nov. 15, 2023. The content of the aforementioned applications, including any intervening amendments thereto, are incorporated herein by reference.

### TECHNICAL FIELD

This present disclosure relates to the technical field of computer equipment, in particular to a case with multi-layer partitioned chambers.

### BACKGROUND

With the continuous development of computer technology, personal computers have gradually entered every household and become an indispensable and important part of people's daily lives. And personal computers have gradually shifted from customized machines from major brand manufacturers to DIY personal computers as the mainstream. Nowadays, people's economic conditions also allow them to upgrade their personal computers, and gradually there are DIY enthusiasts such as “hardware enthusiast”.

At present, most computer case are full-tower structure or mid-tower structure, which are basically single-layer semi-sealed structures. The internal air ducts enter the inside of the case through the ventilation openings on the periphery of the case. After external air enters from the bottom of this type of case, it first passes through the power supply and then comes into contact with the graphics card, which causes the temperature of the air passing through the graphics card to rise, affecting the heat dissipation efficiency of the graphics card.

### SUMMARY

In order to overcome the shortcomings and deficiencies of existing technologies, the objective of this present disclosure is to provide a case with multi-layer partitioned chambers, which solves the problem of graphics card heat dissipation affected by the internal power supply and other components of traditional case through a layered multi-chamber design.

This present disclosure is realized by the following technical solutions:

A case with multi-layer partitioned chambers, including a framework, a first chamber and a second chamber arranged on the framework. The first chamber is used to place graphics cards, the second chamber is used to place a power supply, and the first chamber is located above and spaced apart from the second chamber; one end face of the first chamber near the second chamber is provided with a plurality of first ventilation holes.

Wherein, the first chamber includes a first side plate, a first front plate, and a first bottom plate, the second chamber includes a second side plate, a second front plate, a second bottom plate, and a first top plate. The case further includes a second top plate, a third side plate, and a back plate, wherein the first bottom plate is spaced apart from the first top plate; the first side plate, the first front plate, the first bottom plate, the second top plate, the framework, and the back plate are combined to form a first chamber, and the second side plate, the second front plate, first top plate, third side plate, and the back plate are combined to form a second chamber.

Wherein, the first bottom plate is recessed towards the interior of the first chamber to provided a groove body, and a filter screen is detachably connected inside the groove body.

Wherein, the plurality of first ventilation holes are uniformly distributed at the groove body.

The first side plate, the first front plate, the second side plate, and the second front plate are respectively detachably connected to the framework.

Wherein, a front end of the framework is connected with a first connecting bar, a second connecting bar, and a connecting frame. The distance between the first connecting bar and the second connecting bar matches with a length of the first front plate, and the second connecting bar is located above the connecting frame and spaced apart from the connecting frame; the upper and lower ends of the first front plate are respectively detachably connected to the first connecting bar and the second connecting bar, and the second front plate is detachably connected to the connecting frame.

Wherein, the first connecting bar is provided with a first elastic buckle and a first positioning groove, and the upper end of the first front plate is provided with a first connecting column corresponding to the first elastic buckle and a first positioning column corresponding to the first positioning groove; the second connecting bar is provided with a hanging hole, and the lower end of the first front plate is provided with a hanging hook corresponding to the hanging hole; the connecting frame is provided with a plurality of second elastic buckles and second positioning grooves, and the second front plate is provided with second connection columns corresponding to the second elastic buckles and second positioning columns corresponding to the second positioning grooves.

Wherein, the first bottom plate is further provided with a plurality of threading holes that are connected to the second chamber.

The advantageous effects of this present disclosure is □

The present disclosure relates to a case with multi-layer partitioned chambers, which is designed with a first chamber and a second chamber at intervals. The first chamber is used to place a graphics card, and the second chamber is used to place a power supply; the external air enters into the first chamber from the first ventilation hole through the gap between the first chamber and the second chamber, allowing the graphics card to directly intake cold air, improving the heat dissipation efficiency of the graphics card and solving the problem of graphics card heat dissipation affected by traditional internal components such as power supplies.

### BRIEF DESCRIPTION OF THE DRAWINGS

Further illustration of the present disclosure is provided using the accompanying drawings, but the embodiments shown in the drawings do not constitute any limitation on the present disclosure. For those skilled in the art, other drawings can be obtained based on the following drawings without creative labor.

FIG. 1 is a schematic diagram of the three-dimensional structure of the present disclosure.

FIG. 2 is an exploded view of the present disclosure.

FIG. 3 is a schematic structure diagram of the framework.

FIG. 4 is a schematic structure diagram of the first chamber.

FIG. 5 is a schematic structure diagram of the second chamber.

Reference numbers in the drawings: 100-framework, 101-third side plate, 102-back plate, 103-first connecting bar, 104-second connecting bar, 105-connection frame, 106-first elastic buckle, 107-first positioning groove, 108-hanging hole, 109-second elastic buckle, 110-second positioning groove, 111-second top plate,

200-first chamber, 201-first ventilation hole, 202-first side plate, 203-first front plate, 204-first bottom plate, 205-groove body, 206-filter screen, 207-first connecting column, 208-first positioning column, 209-hanging hook, 210-threading hole,

300-second chamber, 301-second side plate, 302-second front plate, 303-second bottom plate, 304-first top plate, 305-second connecting column, 306-second positioning column.

### DETAILED DESCRIPTION OF THE EMBODIMENTS

In order to make the above objectives, features, and advantages of the present disclosure more obvious and understandable, the embodiments of the present disclosure will be described in detail below in conjunction with the accompanying drawings. Many specific details are elaborated in the following description to facilitate a full understanding of the present disclosure. However, the present disclosure can be implemented in many different ways from those described herein, and those skilled in the art can make similar improvements without violating the concept of the present disclosure. Therefore, the present disclosure is not limited by the specific embodiments disclosed below.

In the description of this present disclosure, it should be understood that, the directional or positional relationships indicated by the terms “center”, “longitudinal”, “transverse”, “length”, “width”, “thickness”, “top”, “bottom”, “left”, “right”, “vertical”, “horizontal”, “top”, “bottom”, “inside”, “outside”, “clockwise”, “anticlockwise”, “axial”, “radial”, and “circumferential”, etc. are based on the directional or positional relationships shown in the accompanying drawings, which is only for the convenience of describing the present disclosure and simplifying the description, and does not indicate or imply that the device or component referred to must have a specific orientation, or be constructed and operated in a specific orientation. Therefore, above terms cannot be understood as limiting the present disclosure.

In addition, the terms “first” and “second” are only used for descriptive objectives and cannot be understood as indicating or implying relative importance or implying the number of technical features indicated. Therefore, the features that are limited to “first” and “second” can explicitly or implicitly include at least one of these features. In the description of this present disclosure, “a plurality of” means at least two, such as two, three, etc., unless otherwise specified.

At present, most computer case are full-tower or mid-tower structures, which are basically single-layer semi-sealed structures. The internal air ducts enter the inside of the case through the ventilation openings on the periphery of the case. After the external air enters into the bottom of the case, the external air first passes through the power supply and then comes into contact with the graphics card, which causes the temperature of the air passing through the graphics card to rise, affecting the heat dissipation efficiency of the graphics card.

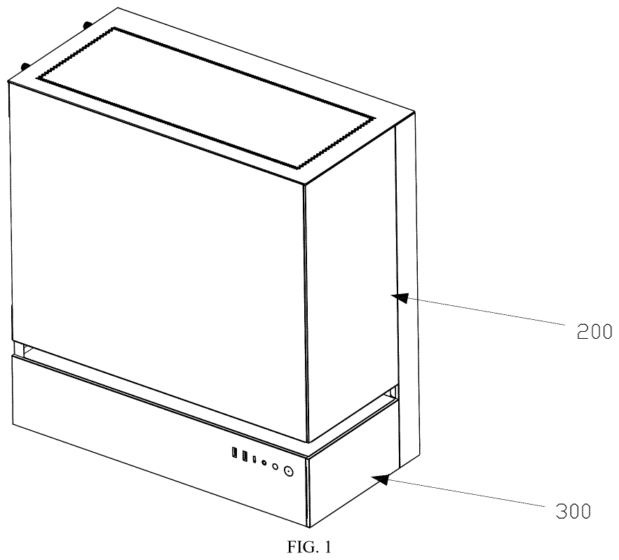

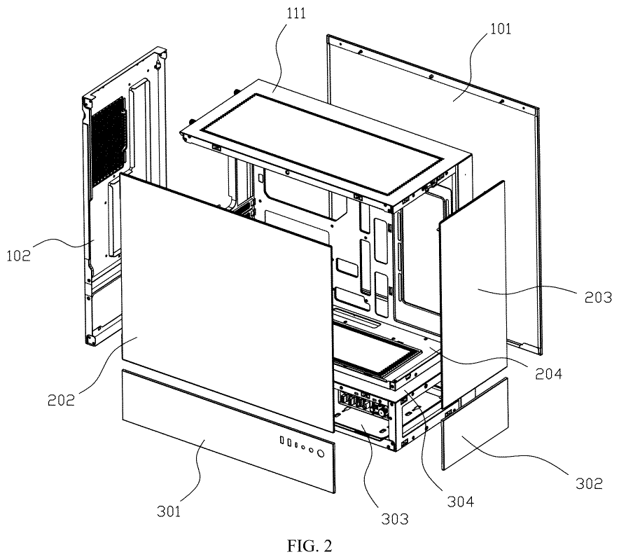

In order to solve the above problems, this embodiment discloses a case with multi-layer partitioned chambers, as shown in FIG. 1 and FIG. 2. The case includes a framework 100, a first chamber 200 and a second chamber 300 arranged on the framework 100. The first chamber 200 is used to place graphics cards, the second chamber 300 is used to place power supplies, and the first chamber 200 is positioned above and is arranged at a distance from the second chamber 300. The first chamber 200 is provided with a plurality of first ventilation holes 201 on one end face near the second chamber 300.

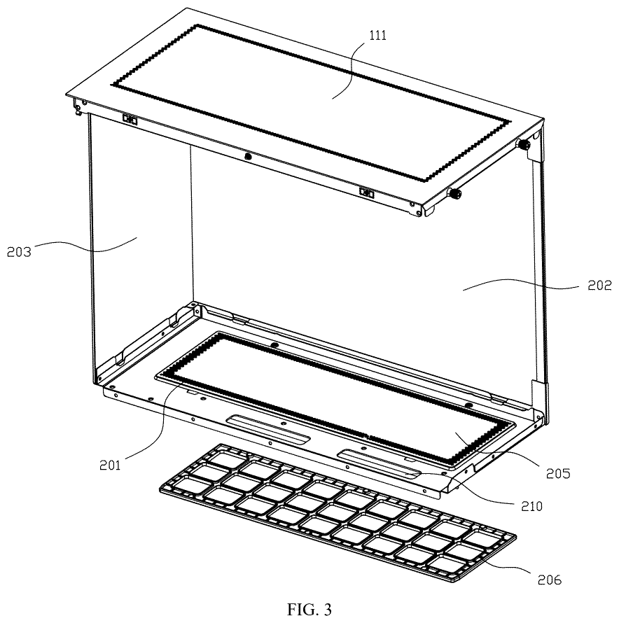

In this embodiment, the shape and structure of the framework 100 can refer to FIG. 3. The framework 100 in this embodiment serves as the support structure for the case skeleton, and connects to a first chamber 200, a second chamber 300 and other components to form the case of this embodiment. That is, the case of this embodiment is designed with the first chamber 200 and the second chamber 300 spaced apart, wherein the first chamber 200 is used to place the graphics card and the second chamber 300 is used to place the power supply. The external air enters into the first chamber 200 from the first ventilation hole 201 through the gap between the first chamber 200 and the second chamber 300, so that the graphics card can directly intake cold air, improve the heat dissipation efficiency of the graphics card, and solve the problem of graphics card heat dissipation caused by the traditional case internal power supply and other components.

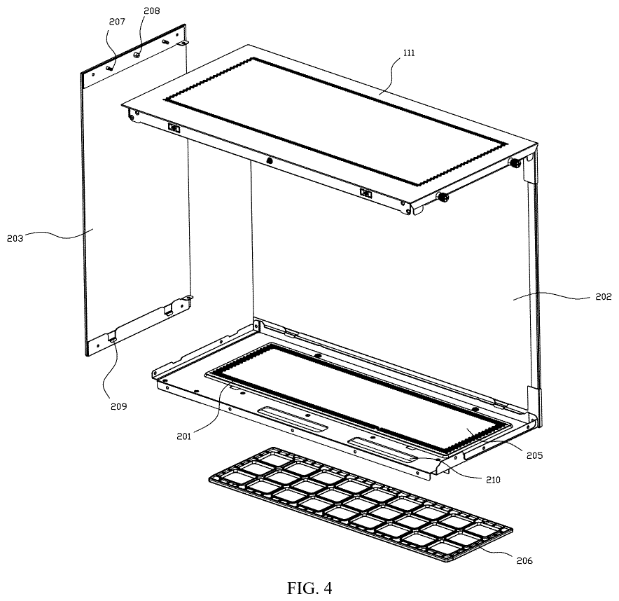

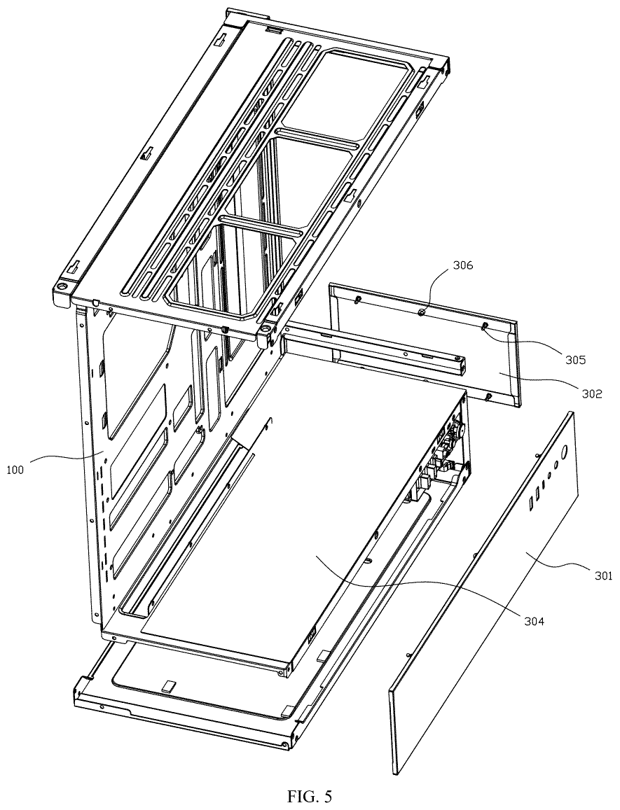

Specifically, as shown in FIGS. 2 to 5, the first chamber 200 includes a first side plate 202, a first front plate 203, and a first bottom plate 204. The second chamber 300 includes a second side plate 301, a second front plate 302, a second bottom plate 303, and a first top plate 304. The case further includes a third side plate 101, a second top plate 111, and a back plate 102. The first bottom plate 204 is spaced apart from the first top plate 304. The first side plate 202, the first front plate 203, the first bottom plate 204, the second top plate 111, the framework 100, and the back plate 102 are combined to form the first chamber 200. The second side plate 301, the second front plate 302, the first top plate 304, the third side plate 101, and the back plate 102 are combined to form the second chamber 300.

Further, the first bottom plate 204 is recessed towards the interior of the first chamber 200 to provide a groove body 205. The groove body 205 is detachably connected to a filter screen 206, preferably magnetic attraction. A plurality of first ventilation holes 201 are evenly distributed at the groove body 205. Above the groove body 205, components such as a cooling fan can be installed at the first bottom plate 204 to draw external air into the first chamber through negative pressure, further enhancing the heat dissipation effect of the graphics card.

From FIG. 3, it can be seen that the front end of the framework 100 is connected with a first connecting bar 103, a second connecting bar 104, and a connecting frame 105. The distance between the first connecting bar 103 and the second connecting bar 104 matches with the length of the first front plate 203. The second connecting bar 104 is located above the connecting frame 105 and is spaced apart from the connecting frame 105.

The upper and lower ends of the first front plate 203 are respectively detachably connected to the first connecting bar 103 and the second connecting bar 104, and the second front plate 302 is detachably connected to the connecting frame 105.

In this embodiment, the first side plate 202, the first front plate 203, the second side plate 301, and the second front plate 302 are respectively detachably connected to the framework 100, achieving rapid maintenance or replacement of internal components of the case.

Specifically, the first connecting bar 103 is provided with a first elastic buckle 106 and a first positioning groove 107. The upper end of the first front plate 203 is provided with a first connecting column 207 corresponding to the first elastic buckle 106 and a first positioning column 208 corresponding to the first positioning groove 107. The second connecting bar 104 is provided with a hanging hole 108, and the lower end of the first front plate 203 is provided with a hanging hook 209 corresponding to the hanging hole 108. The connecting frame 105 is provided with a plurality of second elastic buckles 109 and second positioning grooves 110, and the second front plate 302 is provided with second connection columns 305 corresponding to the second elastic buckles 109 and second positioning columns 306 corresponding to the second positioning grooves 110.

When in use, after the hanging hook 209 at the lower end of the first front plate 203 is inserted into the hanging hole 108, the upper end of the first front plate 203 is pressed in the direction of the first connecting bar 103, and then the first connecting column 207 and the first positioning column 208 are respectively inserted into the first elastic buckle 106 and the first positioning groove 107, so that the first front plate 203 can be quickly installed and fixed through the elastic connection between the first elastic buckle 106 and the first connecting post 207. It should be noted that in this embodiment, the connection manner of the second front plate 302 and the connecting frame 105, the connection manner of the second side plate 301 and the framework 100, and the connection manner of the first front plate 203 and the first connecting bar 103 are the same, so it is not described here for brevity.

Finally, it should be noted that the above embodiments are only used to illustrate the technical solution of the present disclosure, and not to limit the scope of the present disclosure. Although the present disclosure has been described in detail with reference to the preferred embodiments, those skilled in the art should understand that the technical solution of the present disclosure can be modified or equivalently replaced without departing from the essence and scope of the technical solution of the present disclosure.

What is claimed is:

1. A case with multi-layer partitioned chambers, comprising a framework, a first chamber and a second chamber arranged on the framework, wherein the first chamber is located above the second chamber and is spaced apart from the second chamber; and
one end face of the first chamber near the second chamber is provided with a plurality of first ventilation holes.

2. The case with multi-layer partitioned chambers according to claim 1, wherein the first chamber comprises a first side plate, a first front plate, and a first bottom plate; the second chamber comprises a second side plate, a second front plate, a second bottom plate, and a first top plate; the case further comprises a third side plate, a second top plate and a back plate, and the first bottom plate is spaced apart from the first top plate;
the first side plate, the first front plate, the first bottom plate, the framework, and the back plate are combined to form the first chamber, and the second side plate, the second front plate, the first top plate, the third side plate, and the back plate are combined to form the second chamber.

3. The case with multi-layer partitioned chambers according to claim 2, wherein the first bottom plate is recessed towards an interior of the first chamber to provide a groove body, and a filter screen is detachably connected inside the groove body.

4. The case with multi-layer partitioned chambers according to claim 3, wherein the plurality of first ventilation holes are uniformly distributed at the groove body.

5. The case with multi-layer partitioned chambers according to claim 2, wherein the first side plate, the first front plate, the second side plate, and the second front plate are respectively detachably connected to the framework.

6. The case with multi-layer partitioned chambers according to claim 5, a front end of the framework is connected with a first connecting bar, a second connecting bar, and a connecting frame, wherein a distance between the first connecting bar and the second connecting bar matches with a length of the first front plate, and the second connecting bar is located above the connecting frame and spaced apart from the connecting frame;
an upper end and a lower end of the first front plate are respectively detachably connected to the first connecting bar and the second connecting bar, and the second front plate is detachably connected to the connecting frame.

7. The case with multi-layer partitioned chambers according to claim 6, wherein the first connecting bar is provided with a first elastic buckle and a first positioning groove, and the upper end of the first front plate is provided with a first connecting column corresponding to the first elastic buckle and a first positioning column corresponding to the first positioning groove;
the second connecting bar is provided with a hanging hole, and the lower end of the first front plate is provided with a hanging hook corresponding to the hanging hole;
the connecting frame is provided with a plurality of second elastic buckles and second positioning grooves, and the second front plate is provided with second connection columns corresponding to the second elastic buckles and second positioning columns corresponding to the second positioning grooves.

8. The case with multi-layer partitioned chambers according to claim 2, wherein the first bottom plate is further provided with a plurality of threading holes connected to the second chamber.
